(19) United States
(12) Patent Application Publication
(10) Pub. No.: US 2014/0091817 A1
(43) Pub. Date: Apr. 3, 2014

(54) ELECTRONIC DEVICE EQUIPPED WITH CAPACITIVE TYPE TOUCH PANEL

(71) Applicant: PANASONIC CORPORATION, Osaka (JP)

(72) Inventor: Takuma BESSHI, Osaka (JP)

(73) Assignee: PANASONIC CORPORATION, Osaka (JP)

(21) Appl. No.: 14/038,681

(22) Filed: Sep. 26, 2013

(30) Foreign Application Priority Data
Sep. 28, 2012 (JP) 2012-215891

(51) Int. Cl. G01R 27/26

(52) U.S. Cl. CPC G01R 27/2605
USPC 324/684

(57) ABSTRACT

An electronic device includes a touch panel and a position detection circuit operable to output a position signal indicating a position at which the touch panel operated with an object. The detection circuit is operable perform a correction process to capacitance measurement values of electrodes of the touch panel to provide capacitance correction values. The detection circuit is operable to determine whether or not the electronic device is in a holding status in which the electronic device is held based on the capacitance measurement values or the capacitance correction values. The detection circuit is operable to perform a calibration process to correct the correction process if determining that the electronic device is in the holding status. The detection circuit is operable to output the position signal based on the capacitance measurement values or the capacitance correction values. This electronic device can avoid a false detection in approaching detection.

### TECHNICAL FIELD

The present invention relates to an electronic device operated using a capacitive type touch panel.

### BACKGROUND ART

In recent years, with more sophisticated and smaller electronic devices, such as a mobile phone, a music player, and a smartphone, the devices have been required to operate in various ways.

FIG. 14 is a cross-sectional view of conventional input apparatus 20. FIG. 15 is an exploded perspective view illustrating electronic device 30 equipped with input apparatus 20. Input apparatus 20 includes touch panel 1, display apparatus 2, damper sheet 3 and circuit board 4. Touch panel 1 includes cover lens 6, electrodes 7, board 8, electrodes 9, board 10, and connection board 11. Light-transmissive electrodes 7 that have substantially strip shapes arranged on an upper surface of board 8 and are made of, e.g. indium oxide tin. Electrodes 7 are covered by light-transmissive cover lens 6. Light-transmissive electrodes 9 that have substantially strip shapes are arranged on an upper surface of light-transmissive board 10 and are made of, e.g. indium oxide tin. Electrodes 7 extend in a direction perpendicular to electrodes 9. Connection board 11 is a flexible sheet, such as a flexible printed wiring board sandwiched between boards 8 and 10, and has one end electrically connected to electrodes 7 and 9.

Display apparatus 2 is, e.g. a liquid crystal display having an upper surface functioning as a display surface for example. Damper sheet 3 is made of, e.g. rubber and has rectangular aperture 3A.

Circuit board 4 includes wiring board 16, control circuit 17, detection circuit 18, and driving circuit 19. Control circuit 17, detection circuit 18, and driving circuit 19 are provided on an upper surface of wiring board 16. Control circuit 17 is implemented by a semiconductor device, such as a microcomputer. Detection circuit 18 and driving circuit 19 include electronic components, such as resistance or diode. Wiring board 16 is connected to one end of connection board 11. Detection circuit 18 and driving circuit 19 are connected to electrodes 7 and 9 via wirings formed in wiring board 16. Detection circuit 18 and driving circuit 19 are connected to control circuit 17 via wirings formed in wiring board 16.

As shown in FIG. 15, electronic device 30 includes input apparatus 20, upper case 21, lower case 22, and panel sheet 23. Upper case 21 has a substantially box-like shape and is composed of an insulating resin. Panel sheet 23 having a film shape is adhered on an upper surface of upper case 21. Upper case 21 and lower case 22 accommodate input apparatus 20 therein.

An operation of electronic device 30 will be described below. While menus, such as plural icons, are displayed on display apparatus 2, an operator has a finger placed on an upper surface of cover lens 6 above a desired icon. Then, the finger absorbs a part of electric field discharged from electrodes 7 and 9 connected to driving circuit 19. This consequently results in a change in the electric field. This change is detected by detection circuit 18 connected to electrodes 7 and 9. The position touched by the finger is detected by control circuit 17. Then, a predetermined icon is selected, thus allowing display apparatus 2 to display an application corresponding to the selected icon.

When a change in environment, such as temperature or humidity, causes a change in electrical characteristic, electronic device 30 performs a calibration process for touch detection to correct the electrical characteristic so that the touch position can be detected.

When approaching detection in which a finger of an operator can be detected by allowing the finger to merely move close to the upper surface of cover lens 6, an electric field is emitted from electrodes 7 or 9 by driving circuit 19. Then, a change in the electric field caused by the finger of the operator in proximity to the upper surface of cover lens 6 can be detected by detection circuit 18.

A conventional electronic device similar to electronic device 30 is disclosed in Japanese Patent laid-Open Publication No. 2007-208682 and U.S. Patent Application Publication No. 2011/0298735.

### SUMMARY

An electronic device includes a touch panel and a position detection circuit operable to output a position signal indicating a position at which the touch panel operated with an object. The touch panel includes first electrodes and second electrodes facing the first electrodes. The position detection circuit is operable to execute detecting the first capacitance measurement values corresponding to capacitances of the first electrodes, respectively, and second capacitance measurement values corresponding to capacitances of the second electrodes, respectively. The position detection circuit is operable to execute performing a first correction process to the first capacitance measurement values to provide first capacitance correction values, respectively. The position detection circuit is operable to execute performing a second correction process to the second capacitance measurement values to provide second capacitance correction values, respectively. The position detection circuit is operable to execute determining whether or not the electronic device is in a holding status in which the electronic device is held based on the first capacitance measurement values, the first capacitance correction values, the second capacitance measurement values, or the second capacitance correction values. The position detection circuit is operable to execute performing a calibration process to correct the first correction process and the second correction process if determining that the electronic device is in the holding status. The position detection circuit is operable to execute outputting the position signal based on the first capacitance measurement values, the first capacitance correction values, the second capacitance measurement values, or the second capacitance correction values.

This electronic device can avoid a false detection in approaching detection.

### BRIEF DESCRIPTION OF DRAWINGS

FIG. 1 is a cross-sectional view of an electronic device in accordance with an exemplary embodiment of the present invention.

FIG. 2 is an exploded perspective view of the electronic device in accordance with the embodiment.

FIG. 3 is a schematic view of the electronic device in accordance with the embodiment.

FIG. 4 is a flowchart illustrating an operation of the electronic device in accordance with the embodiment.

FIG. 5 illustrates capacitance measurement values of the electronic device in accordance with the embodiment.

FIG. 6 illustrates the capacitance measurement values of the electronic device in accordance with the embodiment.

FIG. 7 illustrates capacitance correction values of the electronic device in accordance with the embodiment.

FIG. 8 is a perspective view of the electronic device in accordance with the embodiment held by an operator.

FIG. 9A illustrates capacitance correction values of the electronic device in accordance with the embodiment.

FIG. 9B illustrates the capacitance correction values of the electronic device in accordance with the embodiment.

FIG. 9C illustrates capacitance correction values of another electronic device in accordance with the embodiment.

FIG. 10 is a flowchart illustrating an operation of the electronic device in accordance with the embodiment.

FIG. 11 illustrates the capacitance correction values of the electronic device in accordance with the embodiment.

FIGS. 12 and 13 are flowcharts illustrating an operation of still another electronic device in accordance with the embodiment.

FIG. 14 is a cross-sectional view of a conventional input apparatus.

FIG. 15 is an exploded perspective view of a conventional electronic device.

### DETAIL DESCRIPTION OF PREFERRED EMBODIMENT

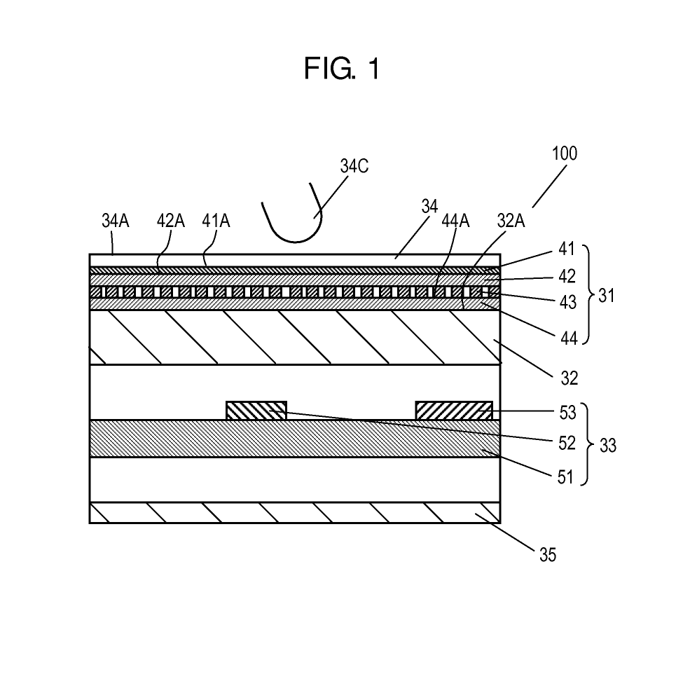

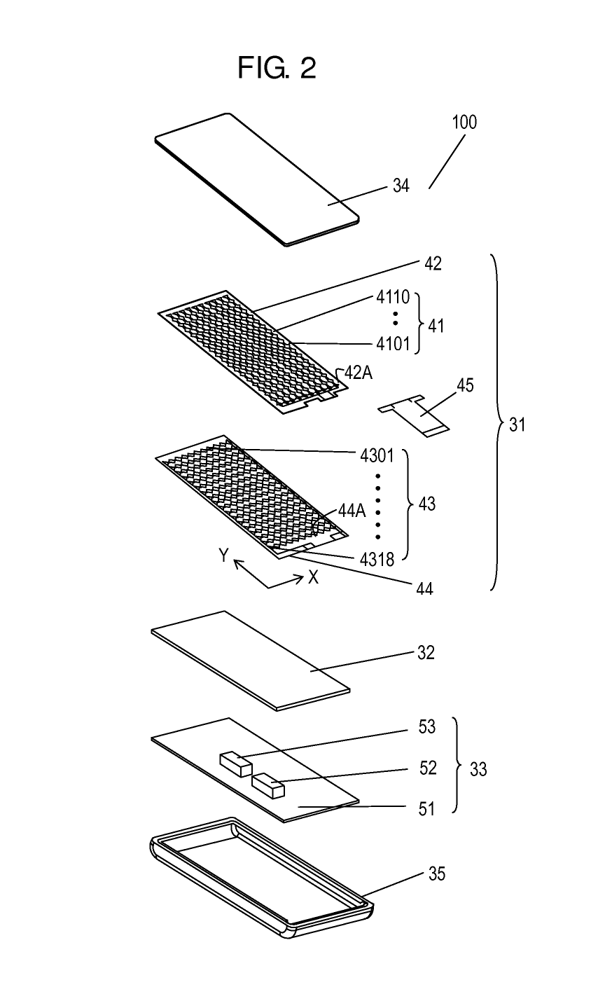

FIGS. 1 and 2 are a cross-sectional view and an exploded perspective view of electronic device 100 in accordance with an exemplary embodiment of the present invention, respectively. Electronic device 100 includes touch panel 31, display apparatus 32, circuit board 33, transparent cover 34, and case 35. Electronic device 100 in accordance with the embodiment is a mobile electronic device, such as a smartphone or a mobile phone.

Touch panel 31 includes electrode group 41, board 42, electrode group 43, board 44, and connection board 45. Boards 42 and 44 are made of light-transmissive material, such as glass or resin.

Electrode group 41 is composed of electrodes 4101 to 4110 having strip shapes that extend in a direction of an X-axis. Electrodes 4101 to 4110 are made of light-transmissive conductive material, such as indium oxide tin or tin oxide. Electrode group 41 is provided on upper surface 42A of board 42 by, e.g. sputtering.

Electrode group 43 is composed of electrodes 4301 to 4318 having strip shapes extending in a direction of a Y-axis perpendicular to the X-axis. Electrodes 4301 to 4318 are made of light-transmissive conductive material, such as indium oxide tin or tin oxide. Electrode group 43 is provided on upper surface 44A of board 44 by, e.g. sputtering. Electrodes 4301 to 4318 are arranged to intersect with electrodes 4101 to 4110 in view from above. Electrodes 4301 to 4318 face electrodes 4101 to 4110. Transparent cover 34 covers electrodes 4101 to 4110 and 4301 to 4318.

Connection board 45 is a flexible sheet, such as a flexible printed wiring board. Connection board 45 is provided between boards 42 and 44 and is adhered to boards 42 and 44 with conductive adhesive, such as conductive paste. Connection board 45 includes plural wirings therein. The wirings have one ends of wirings are connected to electrodes 4101 to 4110 and 4301 to 4318, and the other ends connected to circuit board 33.

Board 42 is adhered to board 44 with adhesive, such as acrylic adhesive, except for a part thereof including connection board 45.

Display apparatus 32 has display surface (upper surface) 32A facing touch panel 31 and is implemented by a display element, such as a liquid crystal display (LCD) or an organic electroluminescence (EL) display. Display surface 32A displays, e.g. an icon thereon. An operator visually confirms a display on display surface 32A of display apparatus 32 via transparent cover 34 and touch panel 31. Transparent cover 34 may have a lens shape for magnifying display surface 32A.

Circuit board 33 includes wiring board 51 has upper and lower surfaces having thereon wirings as well as position detection circuit 52 and display controller 53.

Position detection circuit 52 is implemented by a semiconductor element and performs a predetermined process by, e.g. a hardware composed of a program or logical circuits included therein.

Position detection circuit 52 performs a touch detection process and an approaching detection process. The touch detection process is performed by causing driving signal SG1 to electrode group 41 or electrode group 43 to transmit and emit an electric field, thereby detecting when upper surface 34A of transparent cover 34 is touched by object 34C, such as a finger. The approaching detection process is performed for detecting that object 34C approaches upper surface 34A of transparent cover 34 while not touching upper surface 34A. The driving signal is, e.g. a continuous pulse wave. Position detection circuit 52 sends, to display controller 53, position signal SG2 that indicates the determined position of object 34C and operation signal SG3 that indicates whether object 34C touches transparent cover 34 or approaches transparent cover 34.

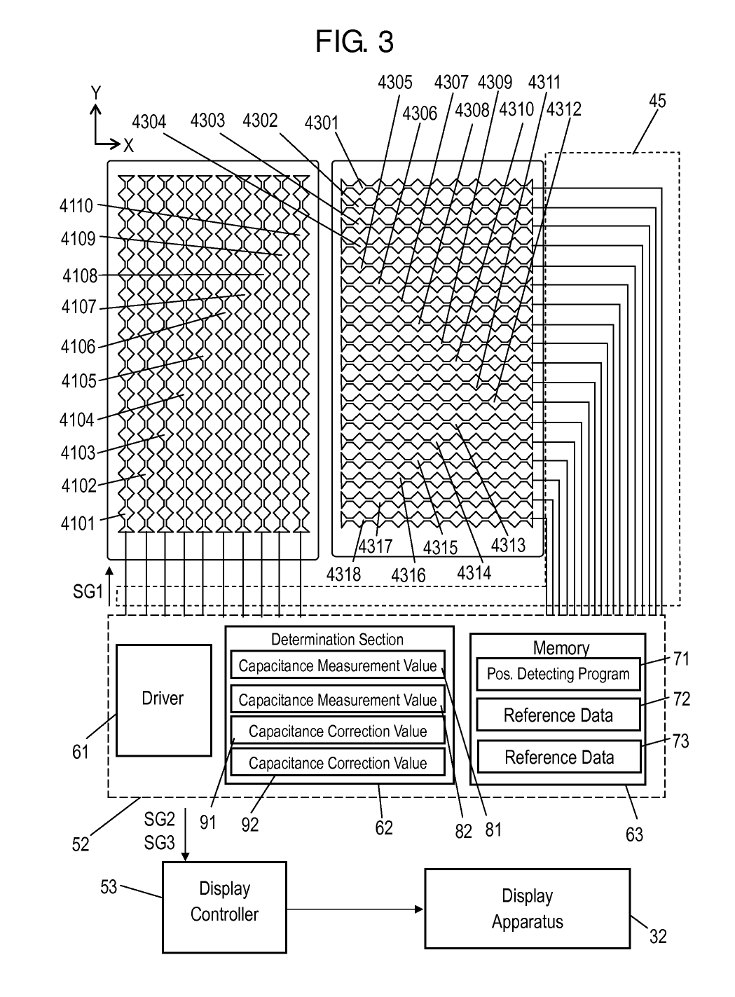

The structure of position detection circuit 52 will be detailed below. FIG. 3 is a schematic view of electronic device 100 for illustrating the connection of position detection circuit 52. Position detection circuit 52 includes driver 61, determination section 62, and memory 63.

Driver 61 emits an electric field through electrodes 4101 to 4110 or electrodes 4301 to 4318.

Driver 61 is connected to electrodes 4101 to 4110 and 4301 to 4318 via connection board 45 connected to circuit board 33. Driver 61 can send driving signal SG1 to electrodes 4101 to 4110 and 4301 to 4318. Specifically, driver 61 can send driving signal SG1 to at least one electrode out of electrodes 4101 to 4110 and 4301 to 4318 to selectively drive the electrode.

Determination section 62 implemented by, e.g. a semiconductor processor detects that object 34C touches transparent cover 34 during the touch detection process, and detects that object 34C approaches transparent cover 34 during the approaching detection process. Determination section 62 is connected to electrodes 4101 to 4110 and 4301 to 4318 via connection board 45 connected to circuit board 33. Determination section 62 detects the capacitances of electrodes 4101 to 4110 and 4301 to 4318. Determination section 62 controls driver 61.

When driver 61 sends driving signal SG1 to at least one electrode of electrodes 4301 to 4318 to drive the electrode to emit driving signal SG1, determination section 62 allows electrodes 4101 to 4110 to receive transmitted driving signal SG1 and detects the capacitances of electrodes 4101 to 4110. Determination section 62 stores the detected capacitances as capacitance measurement values 81.

On the other hand, when driver 61 sends driving signal SG1 to at least one electrode of electrodes 4101 to 4110 to drive the electrode to transmit driving signal SG1, determination section 62 allows electrodes 4301 to 4318 to receive transmitted driving signal SG1 and detects the capacitances of electrodes 4301 to 4318. Determination section 62 stores the detected capacitances as capacitance measurement values 82.

Memory 63 is implemented by a memory element, such as a random access memory (RAM) or a read only memory (ROM). Memory 63 stores position detection program 71 executed by determination section 62 and reference data 72 and 73 used in the approaching detection process.

Reference data 72 and 73 is rewritten when determination section 62 executes position detection program 71 and performs a calibration process based on position detection program 71.

Upon executing position detection program 71, determination section 62 prepares capacitance correction values 91 based on capacitance measurement values 81 and reference data 72, prepares capacitance correction values 92 based on capacitance measurement values 82 and reference data 73, and generates position signal SG2 and operation signal SG3 based on capacitance correction values 91 and 92. In electronic device 100 in accordance with the embodiment, capacitance measurement values 81 corresponding to electrodes 4101 to 4110, plural values of reference data 72, and capacitance correction values 91 are set, respectively. Capacitance measurement values 82 corresponding to electrodes 4301 to 4318, plural values of reference data 73, and capacitance correction values 92 are set, respectively.

Display controller 53 receives position signal SG2 and operation signal SG3 and controls the display of display apparatus 32 by switching the display of display apparatus 32 corresponding to position signal SG2 and operation signal SG3, thereby controlling an operation of electronic device 100.

Transparent cover 34 is fixed to an upper surface of touch panel 31, i.e., on upper surface 41A of electrode group 41 and upper surface 42A of board 42. Transparent cover 34 is made of light-transmissive material, such as glass or resin. Display apparatus 32 is placed beneath touch panel 31. Circuit board 33 is placed beneath display apparatus 32. Case 35 has substantially a rectangular box shape having an upper surface opening. Case 35 accommodates therein touch panel 31, display apparatus 32, and circuit board 33. An upper surface of case 35 is covered by transparent cover 34.

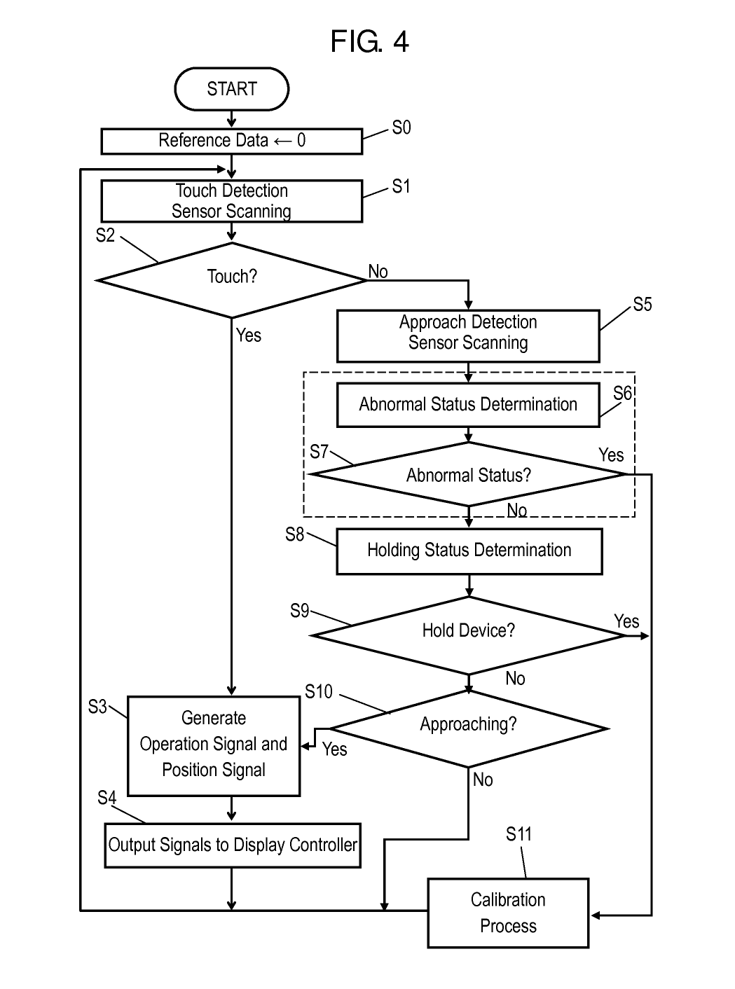

The touch detection process and the approaching detection process executed by position detection circuit 52 will be described below. FIG. 4 is a flowchart illustrating position detection program 71 executed by determination section 62.

The touch detection process is composed of a touch detection sensor scanning (Step S1), a touch determination (Step S2), and a signal generation (Step S3). When electronic device 100 starts, i.e., when the flowchart shown in FIG. 4 starts, determination section 62 initializes reference data 72 and 73 by setting the value of reference data 72 and 73 to a very small value, such as zero (Step S0).

In the touch detection sensor scanning (Step S1), determination section 62 controls driver 61 and switches electrodes 4301 to 4318 to function electrodes 4301 to 4318 as a transmission electrode one by one. Specifically, determination section 62 controls driver 61 to cause driver 61 to supply driving signal SG1 sequentially to electrodes 4301 to 4318 thereby transmitting driving signal SG1 sequentially. Electrodes 4101 to 4110 function as reception electrodes. Whenever driving signals SG1 are transmitted from electrodes 4301 to 4318, determination section 62 detects the capacitances of electrodes 4101 to 4110, respectively, to acquire and store capacitance measurement values 81.

For example, while transmitting driving signal SG1 from electrode 4301, determination section 62 detects the capacitances of electrodes 4101 to 4110 and acquires capacitance measurement values 81, respectively. Next, the transmission is switched to electrode 4302. While transmitting driving signal SG1 from electrode 4302, determination section 62 detects the capacitances of electrodes 4101 to 4110 and acquires and stores capacitance measurement values 81, respectively. This operation is repeated until determination section 62 detects the capacitances of electrodes 4101 to 4110 and acquires and stores capacitance measurement values 81 while transmitting driving signal SG1 from electrode 4318. As described above, every time transmitting driving signal SG1 sequentially from electrodes 4301 to 4318, determination section 62 detects the capacitances of electrodes 4101 to 4110 and acquires and stores capacitance measurement values 81.

Next, in the touch determination (Step S2), as soon as determination section 62 acquires measurement values 81 of the capacitances of electrodes 4101 to 4110, determination section 62 performs a predetermined correction process for touch detection to capacitance measurement values 81 to acquire capacitance correction values 91. Then, determination section 62 compares capacitance correction values 91 with a predetermined threshold value. If at least one electrode of electrodes 4101 to 4110 has capacitance correction value 91 exceeding the predetermined threshold value (“Yes” of Step S2), determination section 62 determines that object 34C touches transparent cover 34. If determination section 62 determines that object 34C touches transparent cover 34 (“Yes” in Step S2), determination section 62 determines an X-coordinate and a Y-coordinate of the position on which object 34C touches transparent cover 34 based on the electrode of electrodes 4101 to 4110 that has capacitance correction value 91 exceeds the threshold value and the electrode out of electrodes 4301 to 4318 that functions as the transmission electrode when capacitance correction value 91 is obtained. On the other hand, if any of capacitance correction values 91 of electrodes 4101 to 4110 is not larger than the predetermined threshold value at Step S2 (“No” in Step S2), determination section 62 determines that object 34C does not touch transparent cover 34.

In the signal generation (Step S3), determination section 62 generates position signal SG2 corresponding to the position on which object 34C touches transparent cover 34 and operation signal SG3 indicating the touching.

The approaching detection process is composed of an approaching detection sensor scanning (Step S5), an approaching determination (Step S10), and a signal generation (Step S3). An operation of position detection circuit 52 based on position detection program 71 upon the operator having object 34C approach an intersection point of electrodes 4105 and 4309 from above upper surface 34A of transparent cover 34 of electronic device 100 will be described below.

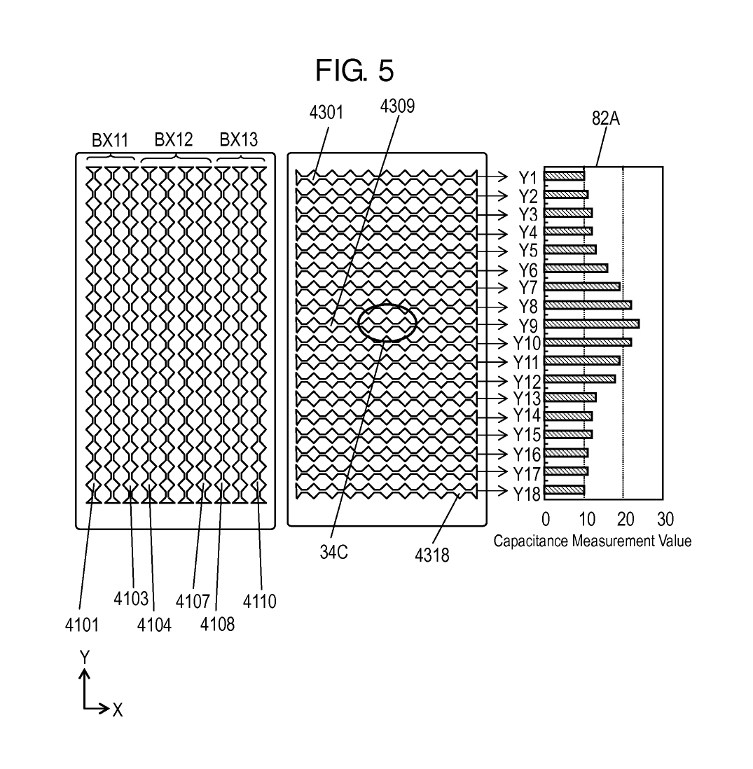

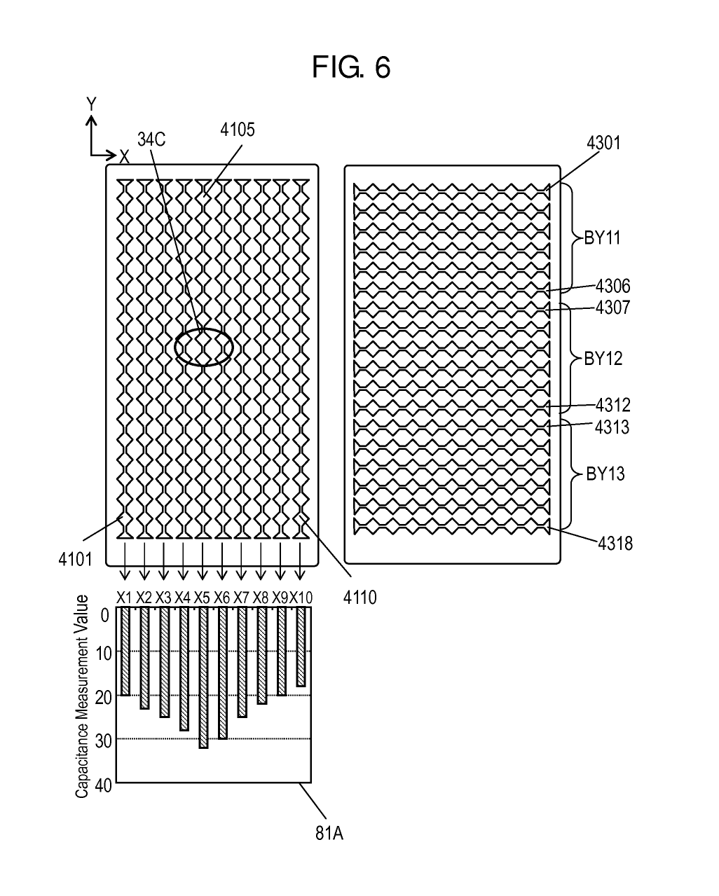

FIG. 5 illustrates capacitance measurement value 82A when electrodes 4101 to 4110 function as transmission electrodes. FIG. 6 illustrates capacitance measurement values 81A when electrodes 4301 to 4318 function as transmission electrodes.

In the approaching detection sensor scanning (Step S5), first, as shown in FIG. 5, determination section 62 controls driver 61 to cause driver 61 to send driving signal SG1 to electrodes 4101 to 4110 to transmit an electric field to cause electrodes 4101 to 4110 to function as transmission electrodes. Electrodes 4101 to 4110 are divided into blocks BX11 to BX13 each of which is composed of plural electrodes. Specifically, electrodes 4101 to 4103 constitute block BX11. Electrodes 4104 to 4107 constitute block BX12. Electrodes 4108 to 4110 constitute block BX13. The electrodes constituting one block simultaneously receive driving signal SG1 and function as transmission electrodes to transmit an electric field. Driver 61 switches, at a high speed, plural electrodes out of electrodes 4101 to 4110 that constitute blocks BX11 to BX13 to allow these electrodes to function as transmission electrodes. Determination section 62 detects the capacitances of electrodes 4301 to 4318 based on electrodes 4301 to 4318 functioning as reception electrodes, respectively, to acquire and store capacitance measurement values 82A.

Determination section 62 measures the capacitances of electrodes 4301 to 4318 to detect capacitance measurement values 82A. Electrodes 4301 to 4318 correspond to Y coordinates Y1 to Y18, respectively. Capacitance measurement values 82A shown in FIG. 5 show that the capacitance at Y coordinate Y9 corresponding to electrode 4309 approached by object 34C is larger than any other capacitance.

Next, as shown in FIG. 6, determination section 62 controls driver 61 to cause driver 61 to send driving signal SG1 to electrodes 4301 to 4318 to transmit an electric field to function electrodes 4301 to 4318 as transmission electrodes. Each of electrodes 4301 to 4318 is divided to blocks BY11 to BY13 each composed of plural electrodes. Specifically, electrodes 4301 to 4306 constitute block BY11. Electrodes 4307 to 4312 constitute block BY12. Electrodes 4313 to 4318 constitute block BY13. Plural electrodes constituting one block simultaneously receive driving signal SG1 and function as transmission electrodes to transmit an electric field. Driver 61 switches, at a high speed, plural electrodes out of electrodes 4301 to 4318 that constitute blocks BY11 to BY13 to allow these electrodes to function as transmission electrodes. Determination section 62 detects the capacitances of electrodes 4101 to 4110, respectively, based on electrodes 4101 to 4110 functioning as reception electrodes to acquire and store capacitance measurement values 81A.

Determination section 62 measures the capacitances of electrodes 4101 to 4110 and acquires and stores capacitance measurement values 81A. Electrodes 4101 to 4110 correspond to X-coordinates X1 to X10, respectively. Capacitance measurement value 81A shown in FIG. 6 shows that the capacitance at X-coordinate X5 corresponding to electrode 4105 approached by object 34C is larger than any other capacitance.

Next, in approaching determination (Step S10), determination section 62 subtracts reference data 72 from capacitance measurement values 81A, thereby calculating capacitance correction values 91A of electrodes 4101 to 4110. Determination section 62 subtracts reference data 73 from capacitance measurement values 82A, thereby calculating calculate capacitance correction values 92A of electrodes 4301 to 4318.

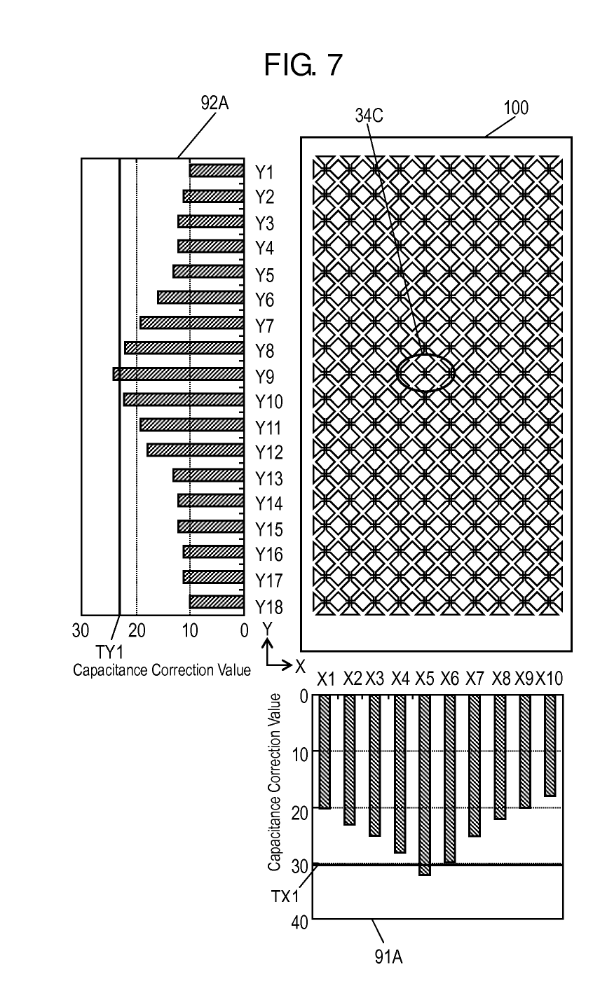

FIG. 7 illustrates capacitance correction values 91A and 92A used for determination section 62 to determine the position close to object 34C. Reference data 72 shows capacitance measurement values 81 of electrodes 4101 to 4110 when object 34C does not approach transparent cover 34. Reference data 73 shows capacitance measurement value 82 of electrodes 4301 to 4318 when object 34C does not approach transparent cover 34. Capacitance correction values 91A and 92A shown in FIG. 7 are reference data 72 and 73 when electrodes 4101 to 4110 and 4301 to 4318 have capacitances of zero.

Determination section 62 compares capacitance correction values 91A with threshold value TX1 and compares capacitance correction values 92A with threshold value TY1. Determination section 62 determines an electrode out of electrodes 4101 to 4110 that has capacitance correction value 91A exceeding threshold value TX1 and an electrode out of electrodes 4301 to 4318 that has capacitance correction value 91B exceeding threshold value TY1 to determine that object 34C approaches a position at which these electrodes intersect each other in view from above (“Yes” in Step S10). If none of capacitance correction values 91A of all electrodes 4101 to 4110 are larger than threshold value TX1 or if none of capacitance correction values 91B of all electrodes 4301 to 4318 are larger than threshold value TY1 at Step S10, determination section 62 determines that object 34C does not approach transparent cover 34 (“No” in Step S10). For example, determination section 62 determines that object 34C approaches the position, X-coordinate X5 and Y-coordinate Y9, at which electrodes 4105 and 4309 intersect with each other in view from above, as shown in FIG. 7.

In signal generation (Step S3), determination section 62 generates position signal SG2 indicating X-coordinate X5 and Y-coordinate Y9 approached by object 34C and operation signal SG3 indicating the approaching.

As described above, electronic device 100 performs both of the touch detection process and the approaching detection process. The operator often has a finger of one hand operate electronic device 100 while having the other hand hold electronic device 100. In the approaching detection process, a false determination in which not the finger operating electronic device 100 but the hand holding electronic device 100 is falsely detected may be caused. In the approaching detection process, another false determination in which electromagnetic noise from the outside of touch panel 31 operates touch panel 31 may be caused.

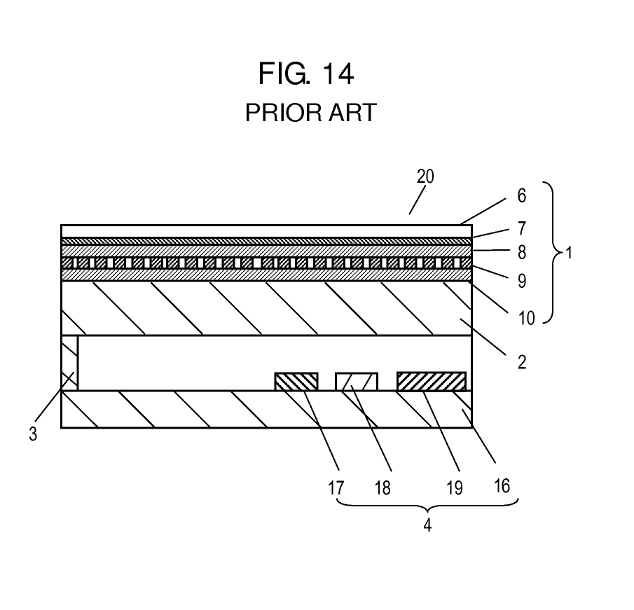

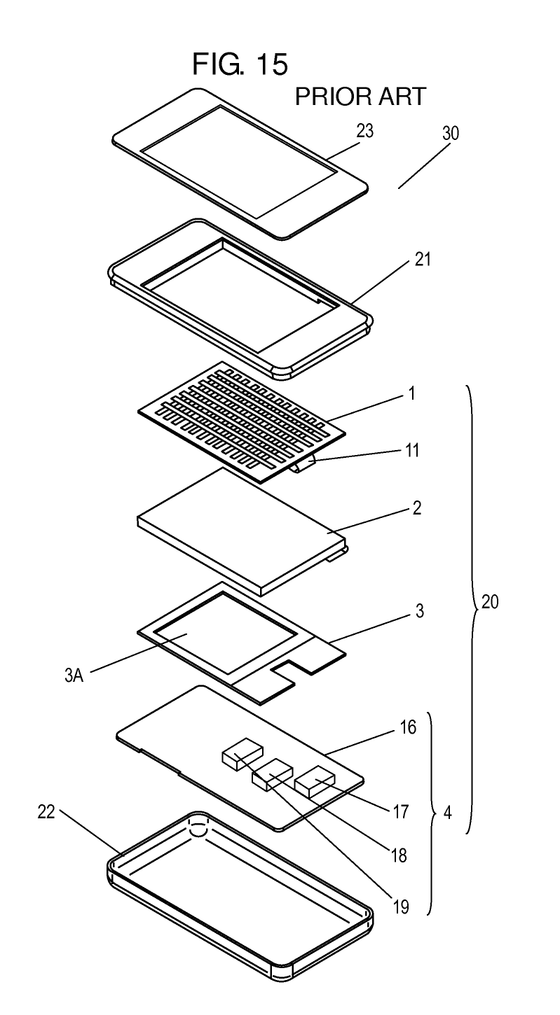

For example, in conventional electronic device 30 shown in FIGS. 14 and 15, since a stronger electric field is emitted at a side surface of the electronic device for the approaching detection than for the touch detection, the approaching detection may cause a false detection in which fingers holding electronic device 30 are undesirably detected even when no finger approaches touch panel 1 while electronic device 30 is held by one hand.

In electronic device 100 in accordance with the embodiment, in order to avoid the above false determinations in the approaching detection process, determination section 62 performs a calibration process to detect a holding status of electronic device 100 and a predetermined status, such as an electromagnetic noise environment, to rewrite reference data 72 and 73. The predetermined status for performing the calibration process will be described below.

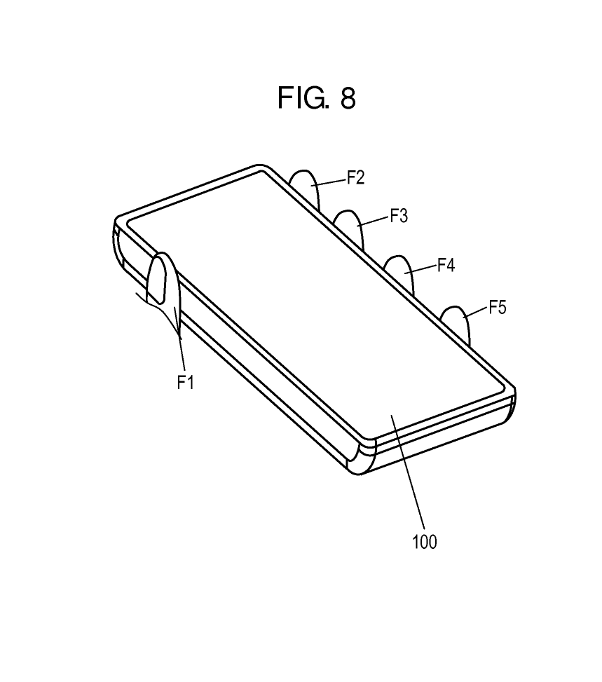

FIG. 8 is a perspective view of electronic device 100 in the holding status in which electronic device 100 is held by a hand of an operator. In order to operate electronic device 100, such as a smartphone or a mobile phone, the operator often have a finger pf one hand operate electronic device 100 while having fingers of the other hand hold electronic device 100. In the status shown in FIG. 8, the operator have one hand hold electronic device 100 while having fingers F2 to F5 contact a right side surface of electronic device 100 and having one finger F1 contact a left side surface of electronic device 100.

In the touch detection process, since a range within which object 34C is detected may be on upper surface 34A of transparent cover 34, the electric field emitted from electrode groups 41 and 43 may be small. In contrast, in the approaching detection process for detecting that object 34C approached transparent cover 34, since a range within which object 34C is detected is over upper surface 34A of transparent cover 34, the electric field emitted from electrode groups 41 and 43 is large. Thus, there may be a false detection where fingers F1 to F5 contacting the left and right side surfaces of electronic device 100 are undesirably detected by electronic device 100.

If the operator does not operate touch panel 31 in the holding status shown in FIG. 8, none of capacitance correction values 91 of electrodes 4101 to 4110 are larger than the predetermined threshold value at Step S2 of the flowchart shown in FIG. 4, and hence, determination section 62 determines that object 34C does not touch transparent cover 34 (“No” in Step S2).

If determination section 62 determines in Step S2 that object 34C does not touch transparent cover 34 (“No” in Step S2), determination section 62 performs the above-described approaching detection sensor scanning (Step S5). Determination section 62 acquires and stores capacitance measurement values 81, which indicate the capacitance distribution along the direction of the X-axis, and capacitance measurement values 82, which indicate the capacitance distribution along the direction of the Y-axis.

Determination section 62 calculates capacitance correction values 91 by subtracting reference data 72 from capacitance measurement values 81, and calculates capacitance correction values 92 by subtracting reference data 73 from capacitance measurement values 82.

Then, determination section 62 performs an abnormality determination to determine whether capacitance correction values 91 and 92 are abnormal or not (Steps S6 and S7). The abnormality determination at Steps S6 and S7 will be described later. In Step S7, when determination section 62 determines that capacitance correction values 91 and 92 are not abnormal (“No” in Step S7), determination section 62 performs a holding status determination to determine whether electronic device 100 is held by a hand of the operator, as shown in FIG. 8 (Steps S8 and S9). Conditions for determining the holding status at Step S9 will be described below.

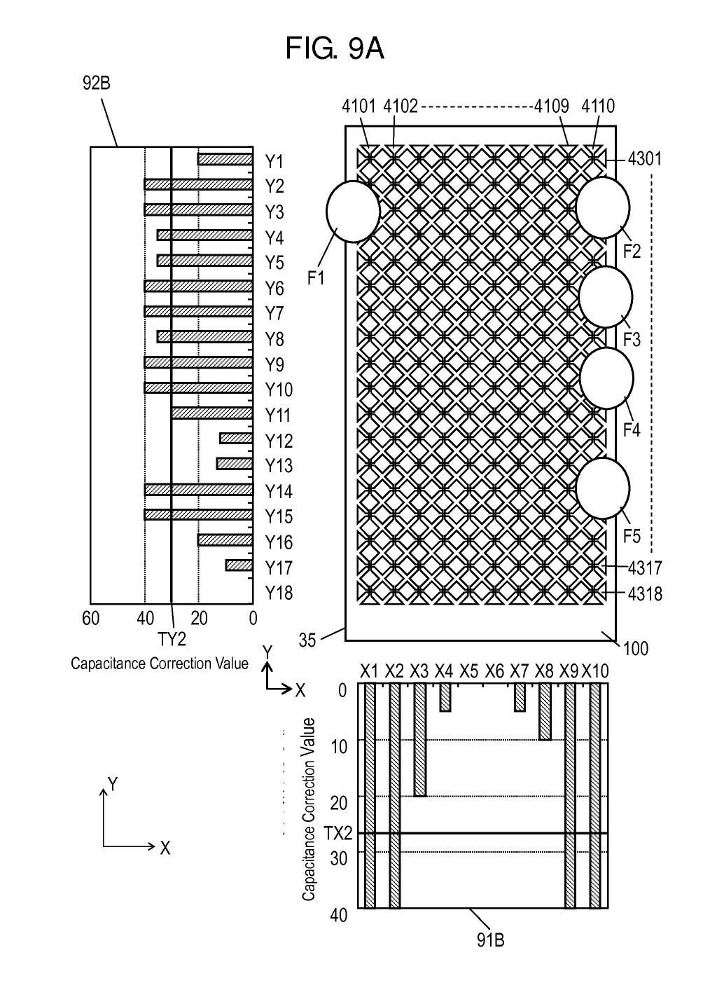

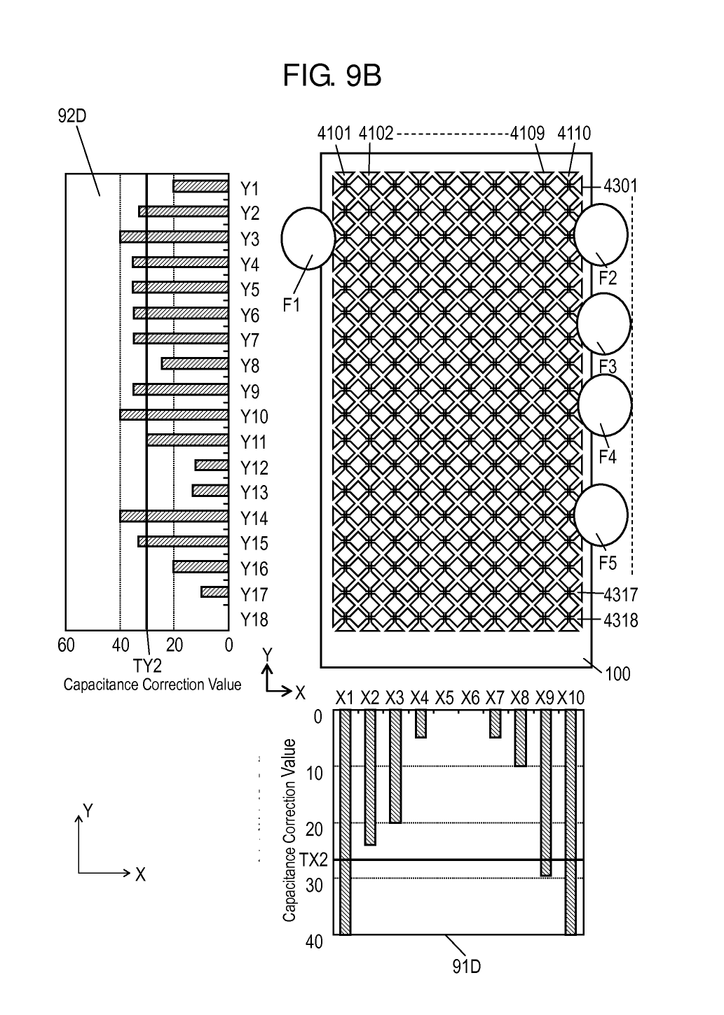

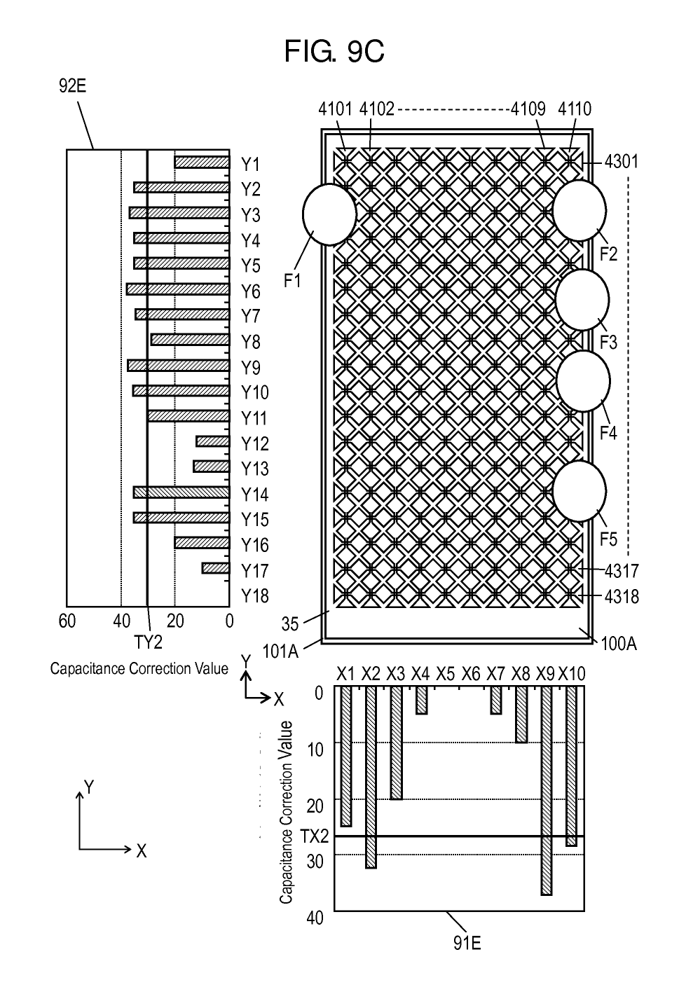

FIG. 9A illustrates capacitance correction values 91B and 92B of electronic device 100 in the holding status. In the holding status determination at Steps S8 and S9, determination section 62 determines whether or not capacitance correction values 91B and 92B satisfy predetermined holding conditions. This determination is made by determining, for example, whether all the following conditions (9A-1) to (9A-4) are satisfied or not. Specifically, when all the following conditions (9A-1) to (9A-4) are satisfied, determination section 62 determines that electronic device 100 is in the holding status (“Yes” in Step S9). When at least one of conditions (9A-1) to (9A-4) is not satisfied, determination section 62 determines that electronic device 100 is not in the holding status (“No” in Step S9).

(9A-1) Electrode 4101 out of electrodes 4101 to 4110 located at one end of the array of electrodes 4101 to 4110 and electrode 4102 out of electrodes 4101 to 4110 adjacent to electrode 4101 have capacitance correction values 91B exceeding threshold value TX2.

(9A-2) Electrode 4110 out of electrodes 4101 to 4110 located at another end of the array of electrodes 4101 to 4110 and electrode 4109 out of electrodes 4101 to 4110 adjacent to electrode 4110 have capacitance correction values 91B exceeding threshold value TX2.

(9A-3) Two electrodes 4105 and 4106 out of electrodes 4101 to 4110 located at a center of electrodes 4101 to 4110 have capacitance correction values 91B smaller than threshold value TX2.

(9A-4) Not fewer than half of electrodes 4301 to 4318 have capacitance correction values 92B exceeding threshold value TY2.

FIG. 9B illustrates capacitance correction values 91D and 92D of electronic device 100 held by fingers F1 to F5 with a smaller force than the holding status shown in FIG. 9A. In this case, determination section 62 determines that electronic device 100 is in the holding status if the following conditions (9B-1) to (9B-4), for example, are all satisfied (“Yes” in Step S9). If at least one of conditions (9B-1) to (9B-4) is not satisfied, on the other hand, determination section 62 determines that electronic device 100 is not in the holding status (“No” in Step S9).

(9B-1) Electrode 4101 out of electrodes 4101 to 4110 located at one end of the array of electrodes 4101 to 4110 has capacitance correction value 91D exceeding threshold value TX2.

(9B-2) Electrode 4110 out of electrodes 4101 to 4110 located at another end of the array of electrodes 4101 to 4110 has capacitance correction value 91D exceeding threshold value TX2.

(9B-3) Electrode 4105 located at a center of electrodes 4101 to 4110 has capacitance correction value 91D smaller than threshold value TX2.

(9B-4) Not fewer than half of electrodes 4301 to 4318 have capacitance correction values 92D exceeding threshold value TY2.

FIG. 9C illustrates capacitance correction values 91E and 92E of another electronic device 100A in the holding status in accordance with the embodiment. In FIG. 9C, components identical to those of electronic device 100 shown in FIGS. 1, 2, and 9A are denoted by the same reference numerals. Electronic device 100A further includes shield element 101A provided at case 35 to surround electrodes 4101 to 4110 and 4301 to 4318. Shield element 101A is made of conductive material, such as metal. Shield element 101A can prevent the false detection of touch panel 31 due to the electromagnetic noise around electronic device 100A. In electronic device 100 covered with an external metal case, the external case functions as shield element 101A of electronic device 100A. Thus, electronic device 100 can operate similarly to electronic device 100A. In the electronic device 100A in the holding status determination at Steps S8 and S9, determination section 62 determines whether or not capacitance correction values 91E and 92E satisfy predetermined holding conditions. Shield element 101A reduces the influence of fingers F1 to F5 and reduces electric field at the outer periphery of touch panel 31. Thus, the determination is made, for example, based on whether or not all the following conditions (9C-1) to (9C-4) are satisfied. Specifically, when all the following conditions (9C-1) to (9C-4) are satisfied, determination section 62 determines that electronic device 100A is in the holding status (“Yes” in Step S9). When at least one of conditions (9C-1) to (9C-4) is not satisfied, on the other hand, determination section 62 determines that electronic device 100A is not in the holding status (“No” in Step S9).

(9C-1) Electrode 4102 out of electrodes 4101 to 4110 adjacent to electrode 4101 located at one end of the array of electrodes 4101 to 4110 has capacitance correction value 91E exceeding threshold value TX2.

(9C-2) Electrode 4109 out of electrodes 4101 to 4110 adjacent to electrode 4110 located at another end of the array of electrodes 4101 to 4110 has capacitance correction value 91E exceeding threshold value TX2.

(9C-3) Electrode 4105 out of electrodes 4101 to 4110 located at a center of electrodes 4101 to 4110 has capacitance correction value 91E smaller than threshold value TX2.

(9C-4) Not fewer than half of electrodes 4301 to 4318 have capacitance correction values 92E exceeding threshold value TY2.

As described above, the statuses shown in FIGS. 9A to 9C may occur in electronic device 100. Thus, in the holding status determination at Steps S8 and S9, determination section 62 determines whether or not capacitance correction values 91 and 92 satisfy, for example, the following conditions (9-1) to (9-4). Specifically, if all the following conditions (9-1) to (9-4) are satisfied, determination section 62 determines that electronic device 100 is in the holding status (“Yes” in Step S9). If at least one of conditions (9-1) to (9-4) is not satisfied, on the other hand, determination section 62 determines that electronic device 100 is not in the holding status (“No” in Step S9).

(9-1) At least one of electrode 4101 out of electrodes 4101 to 4110 located at one end of the array of electrodes 4101 to 4110 and electrode 4102 adjacent to electrode 4101 have capacitance correction value 91 exceeding threshold value TX2.

(9-2) At least one of electrode 4110 out of electrodes 4101 to 4110 located at another end of the array of electrodes 4101 to 4110 and electrode 4109 adjacent to electrode 4110 have capacitance correction value 91 exceeding threshold value TX2.

(9-3) Electrode 4105 located at a center of electrodes 4101 to 4110 has capacitance correction value 91 smaller than threshold value TX2.

(9-4) Not fewer than half of electrodes 4301 to 4318 have capacitance correction values 92B exceeding threshold value TY2.

In the first holding status after starting of the device, reference data 72 and 73 has a very small value, such as zero. Thus, capacitance correction values 91 and 92 shown in FIG. 9A are substantially identical to capacitance measurement values 81 and 82, and thus satisfy all the above conditions (9-1) to (9-4). Therefore, determination section 62 determines that electronic device 100 is in the holding status (“Yes” in Step S9) in the first holding status after starting of the device.

If determination section 62 determines in Step S9 that electronic device 100 is in the holding status (“Yes” in Step S9), determination section 62 performs a calibration process (Step S11). In the calibration process at Step S11, determination section 62 rewrites reference data 72 to provide reference data 72 with capacitance measurement value 81, and rewrites reference data 73 to provide reference date 73 with capacitance measurement value 82, thereby update reference data 72 and 73.

In electronic device 100 in accordance with the embodiment, in order to determine the holding status in all of the statuses shown in FIGS. 9A to 9C, determination section 62 determines the holding status by determining whether or not all conditions (9-1) to (9-4) are satisfied. If it is not necessary to determine the holding status in at least one status out of the statuses shown in FIGS. 9A to 9C, determination section 62 of electronic device 100 may determine the holding status by determining whether or not all the conditions of at least one condition group of a condition group containing conditions (9A-1) to (9A-4), a condition group containing conditions (9B-1) to (9B-4), and a condition group containing conditions (9C-1) to (9C-4) are satisfied.

Since the above described processes at Steps S1 to S11 are performed at a high speed, electronic device 100 is maintained in the holding status without being operated by fingers F1 to F5 of the hand of the operator even after the calibration process at Step S11 is performed. Thus, after the calibration process of Step S11, determination section 62 performs the processes of Steps S1, S2, and S5 to S9. A holding status determination process at Steps S8 and S9 out of these processes causes reference data 72 to be identical to capacitance correction values 91B, 91D, or 91E shown in FIGS. 9A to 9C and causes reference data 72 to be identical to capacitance correction values 92B, 92D, or 92E shown in FIGS. 9A to 9C. Thus, capacitance correction values 91 and 92 are substantially zero. Therefore, all the above conditions (9-1), (9-2), and (9-3) are not satisfied, and thus, determination section 62 determines at Step S9 that electronic device 100 is not in the holding status (“No” in Step S9). If determination section 62 determines at Step S9 that electronic device 100 is not in the holding status (“No” in Step S9), determination section 62 performed at Step S10 the above-described approaching determination, calculates capacitance correction values 91A and 92A shown in FIG. 7, and determines whether or not object 34C approaches transparent cover 34. If object 34C approaches transparent cover 34 (“Yes” in Step S10), determination section 62 determines the approached position and generates operation signal SG3 indicating the approaching and position signal S3 indicating the approached position (Step S3). If determination section 62 determines that object 34C does not approach transparent cover 34 (“No” in Step S10), determination section 62 performs the processes from Step S1.

Determination section 62 performs the holding status determination at Steps S8 and S9 at an interval not longer than 2 seconds, and desirably at an interval ranging from 10 msec to 50 msec. This operation allows the approaching detection process to be performed quickly while electronic device 100 being operated by the operator.

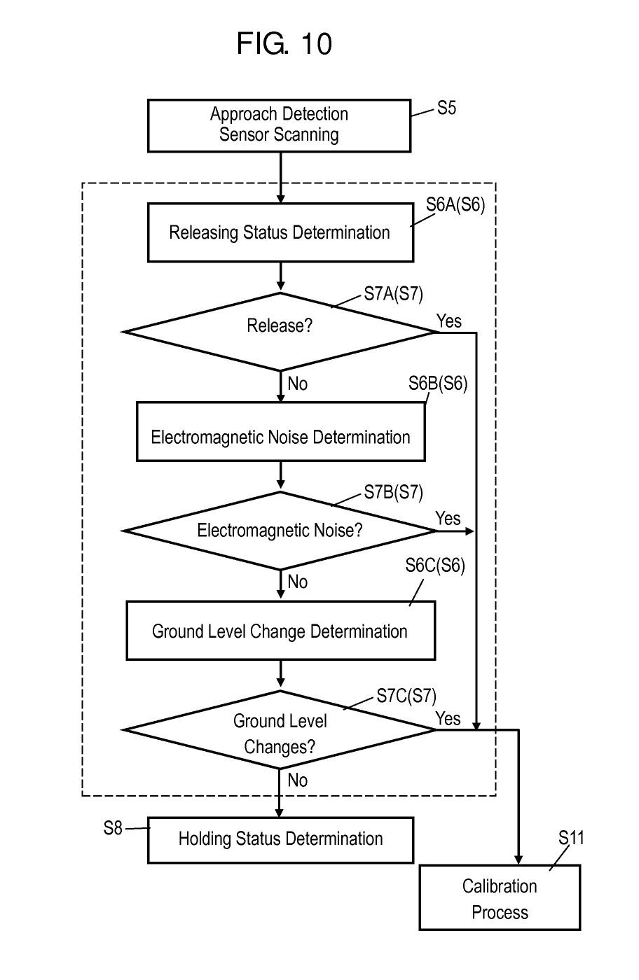

Next, the abnormality determination process at Steps S6 and S7 will be described below. FIG. 10 is a flowchart illustrating the operation of electronic device 100 in the abnormality determination process at Steps S6 and S7 shown in FIG. 4. The abnormality determination process of Steps S6 and S7 includes a releasing status determination (Steps S6A and S7A), an electromagnetic noise determination (Steps S6B and S7B), and a ground level change determination (Steps S6C and S7C).

First, the releasing status determination in Steps S6A and 7A to determine a transition from the holding status to a releasing status in which the operator releases fingers F1 to F5 of the hand of the operator from electronic device 100 (Steps S6A and 7A) and the calibration process in the releasing status (Step S11) will be described below.

When the operator completes the operation and releases the hand holding electronic device 100 (fingers F1 to F5) from touch panel 31 in the releasing status, the detected capacitances of electrodes 4101 to 4110 and 4301 to 4318 change. Determination section 62 acquires capacitance correction values 91 and 92 provided based on reference data 72 and 73 updated in the calibration process at Step S11 by the approaching detection sensor scanning at Step S5 in the holding status.

Next, determination section 62 determines whether or not capacitance correction values 91 and 92 satisfy predetermined abnormality conditions (Step S6). The predetermined abnormality conditions are, for example, whether or not at least one of the following conditions (6A-1) and (6A-2) is satisfied.

(6A-1) At least one electrode of electrodes 4101 to 4110 has capacitance correction value 91 is negative.

(6A-2) At least one electrode of electrodes 4301 to 4318 has capacitance correction value 92 is negative.

Reference data 72 updated in the holding status of electrodes 4101, 4102, 4109, and 4110 located near both ends of the array of electrodes 4101 to 4110 are larger than reference data 72 of electrodes out of electrodes 4101 to 4110 other than electrodes 4101, 4102, 4109, and 4110. In the releasing status, capacitance measurement values 81 of electrodes 4101 to 4110 are small. Thus, electrodes 4101, 4102, 4109, and 4110 corresponding to X-coordinates X1, X2, X9, and X10 have capacitance correction values 91 which are negative, thus satisfying condition (6A-1). If determination section 62 in the abnormality determination at Step S7 determines that at least one of capacitance correction values 91 and 92 satisfies at least one of conditions (6A-1) and (6A-2) (“Yes” in Step S7), determination section 62 performs the calibration process of Step S11. In the calibration process at Step S11, as described above, determination section 62 updates reference data 72 and 73 by rewriting reference data 72 and 73 to provide reference data 72 and 73 with capacitance measurement values 81 and 82, respectively.

If, on the other hand, determination section 62 in the abnormality determination at Step S7 determines that capacitance correction values 91 and 92 satisfies none of conditions (6A-1) and (6A-2) (“No” in Step S7), determination section 62 does not perform the calibration process at Step S11 and does not rewrite reference data 72 and 73 to leave reference data 72 and 73 as they are, and then, performs an electromagnetic noise determination at Steps S6B and S7B.

Next, the calibration process based on the electromagnetic noise determination in Steps S6B and S7B will be described.

In electronic device 100, electrodes 4301 to 4318 function both as the reception electrodes and the transmission electrodes. Thus, electrodes 4301 to 4318 are prevented from functioning as a ground plate, and tend to receive electromagnetic noise emitted from display apparatus 32.

Determination section 62 determines whether or not the electromagnetic noise is received from display apparatus 32 by determining whether or not capacitance correction values 91C and 92C satisfy predetermined abnormality conditions (Step S6).

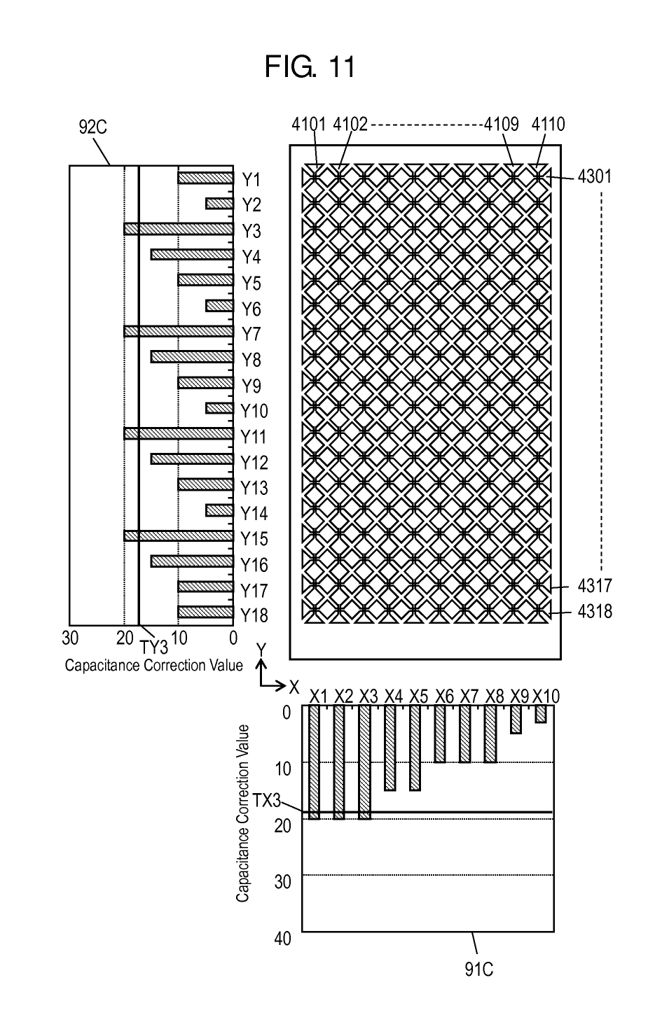

FIG. 11 illustrates capacitance correction values 91C and 92C in the status where the electromagnetic noise is received. Determination section 62 determines that abnormality conditions are satisfied if capacitance correction values 91C and 92C satisfy, for example, both of the following conditions (6B-1) and (6B-2) or both of conditions (6B-3) and (6B-4) (“Yes” in Step S6).

(6B-1) Four or more electrodes out of electrodes 4301 to 4318 have capacitance correction values 92 exceeds threshold value TY3 while at least one electrode out of electrodes 4301 to 4318 has capacitance correction value 92 not larger than threshold value TY3.

(6B-2) Any two of the electrodes out of electrodes 4301 to 4318 having capacitance correction values 92 exceeding threshold value TY3 are not adjacent to each other and are not arranged continuously.

(6B-3) Three or more electrodes out of electrodes 4101 to 4110 have capacitance correction values 91 exceeds threshold value TX3 while at least one electrode out of electrodes 4301 to 4318 has capacitance correction value 91 not larger than threshold value TX3.

(6B-4) Any two of the electrodes out of electrodes 4101 to 4110 having capacitance correction values 91 exceeding threshold value TX3 are not adjacent to each other and are not arranged continuously.

As shown in FIG. 11, capacitance correction values 92C satisfies conditions (6B-1) and (6B-2). Hence, determination section 62 determines that capacitance correction values 91C and 92C satisfy the abnormality conditions (“Yes” in Step S7). If determination section 62 determines in Step S7 that capacitance correction values 91C and 92C satisfy the abnormality conditions (“Yes” in Step S7), determination section 62 performs the calibration process at Step S11. In the calibration process at Step S11, determination section 62 updates reference data 72 and 73 by rewriting reference data 72 and 73 to provide reference date with capacitance measurement values 81 and 82, as described above.

Next, the calibration process based on the determination of a ground level change at Steps S6C and S7C will be described below.

In electronic device 100, electrodes 4301 to 4318 function both as the reception electrodes and the transmission electrodes. Thus, upon having the connection board move between electrodes 4301 to 4318, display apparatus 32 may change a ground level for detecting the capacitances.

Determination section 62 determines whether or not the ground level is changed by determining whether or not capacitance correction values 91 and 92 satisfy a predetermined abnormality condition of the following conditions (6C-1) and (6C-2) (Step S6).

(6C-1) At least one electrode of electrodes 4101 to 4110 has capacitance correction value 91 which is negative.

(6C-2) At least one electrode of electrodes 4301 to 4318 has capacitance correction value 92 which is negative.

If determination section 62 determines an abnormality by determining that capacitance correction values 91 and 92 satisfy at least one of the above conditions (6C-1) and (6C-2) (“Yes” in Step S7), determination section 62 performs the calibration process (Step S11) to update reference data 72 and 73 by providing reference data 72 and 73 with capacitance measurement values 81 and capacitance measurement values 82, respectively. In the calibration process at Step S11, determination section 62 updates reference data 72 and 73 by rewriting reference data 72 and 73 to provide reference data 72 and 73 with capacitance measurement values 81 and 82, as described above.

If determination section 62 determines, on the other hand, that capacitance correction values 91 and 92 satisfy none of the above conditions (6C-1) and (6C-2) (“No” in Step S7), determination section 62 does not perform the calibration process at Step S11, and does not update reference data 72 and 73 to leave reference data 72 and 73 as they are, and then, determines the holding status at Step S8.

As described above, electronic device 100 performs the calibration process depending on the holding status, the releasing status, the electromagnetic noise, and the change of the ground level, thereby preventing object 34C from being falsely detected.

In electronic device 100 in accordance with the embodiment, determination section 62 performs the releasing status determination (Steps S6A and S7A) in the abnormality determination process of Steps S6 and S7, the electromagnetic noise determination (Steps S6B and S7B), and the ground level change determination (Steps S6C and S7C) in this order. This order is not limited to this. Determination section 62 may perform the releasing status determination (Steps S6A and S7A), the electromagnetic noise determination (Steps S6B and S7B), and the ground level change determination (Steps S6C and S7C) in any order. Alternatively, determination section 62 may not perform an unnecessary determination out of the releasing status determination (Steps S6A and S7A), the electromagnetic noise determination (Steps S6B and S7B), and the ground level change determination (Steps S6C and S7C).

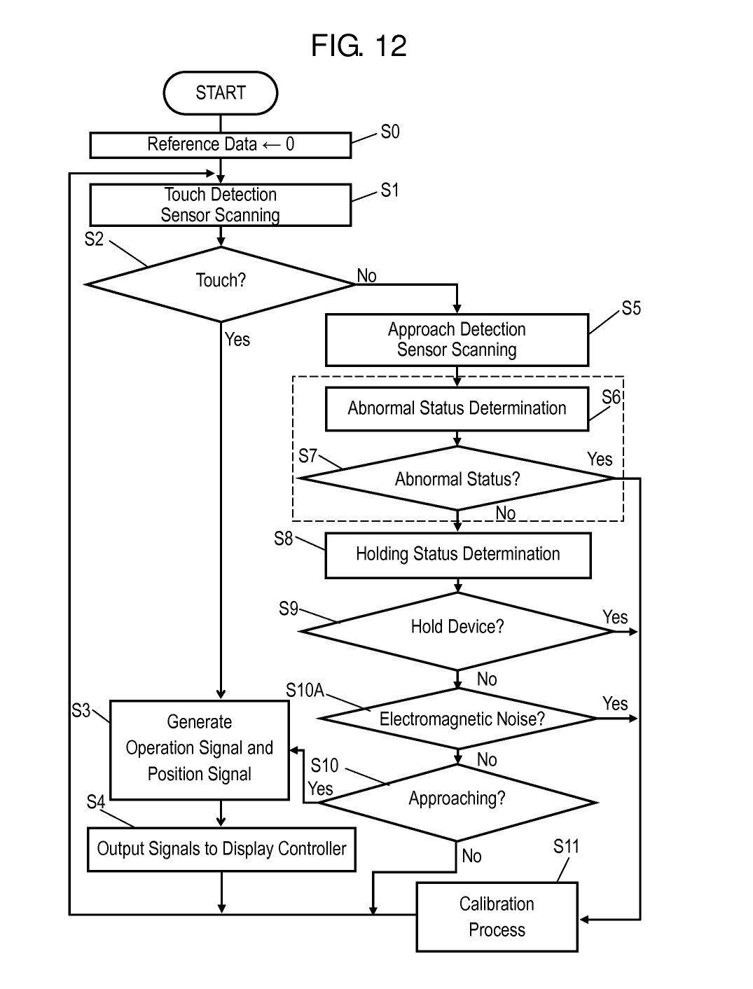

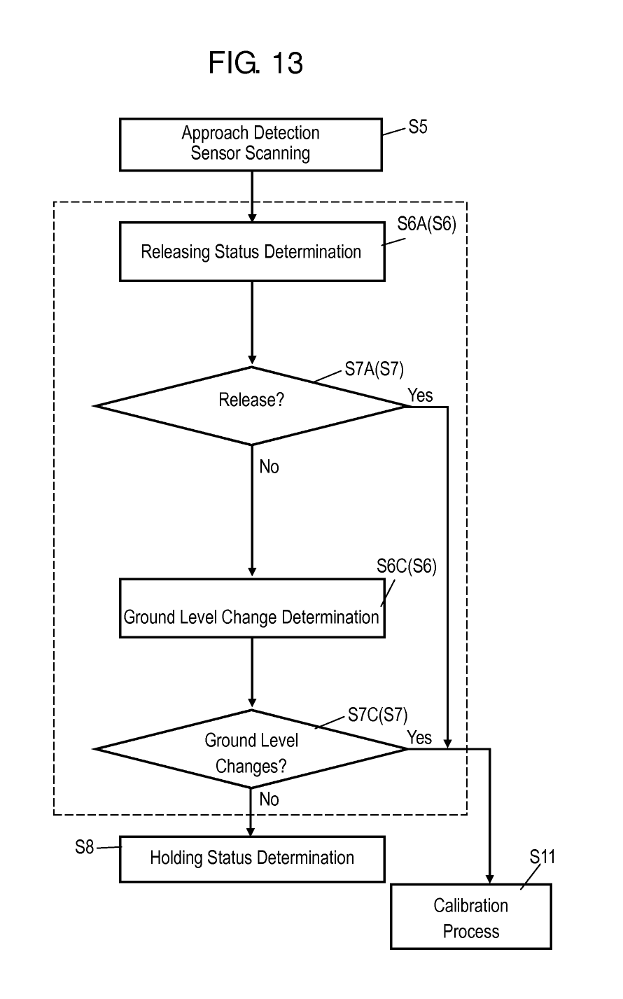

FIGS. 12 and 13 are a flowchart illustrating an operation of still another electronic device 100 in accordance with the embodiment. In FIGS. 12 and 13, components identical to those of the flowcharts shown in FIGS. 4 and 10 are denoted by the same reference numerals. The flowchart shown in FIG. 13 does not include the electromagnetic noise determination process at Step S6B of electronic device 100 shown in FIG. 10. The flowchart shown in FIG. 12 includes the electromagnetic noise determination (Step S10A) between the holding status determination of electronic device 100 at Step S9 and the approaching determination at Step S10.

Determination section 62 determines an abnormality due to electromagnetic noise by determining whether or not at least one of the following conditions (10A-1) and (10A-2) is satisfied at Step S10A.

(10A-1) Three or more electrodes out of electrodes 4101 to 4110 not adjacent to one another have capacitance correction values 91C exceeding threshold value TX3.

(10A-2) Three or more electrodes out of electrodes 4301 to 4318 not adjacent to one another have capacitance correction values 92C exceeding threshold value TY3.

If it is determined at Step S9 that electronic device 100 is not in the holding status (“No” in Step S9), determination section 62 determines whether or not capacitance correction values 91 and 92 satisfy at least one of conditions (10A-1) and (10A-2) (Step S10A). If determination section 62 determines at Step S10A that capacitance correction values 91 and 92 satisfy at least one of conditions (10A-1) and (10A-2) (“Yes” in Step S10A), determination section 62 performs the calibration process (Step S11) to update reference data 72 and 73 by providing reference data 72 and reference date 73 with capacitance measurement value 81 and capacitance measurement value 82, respectively.

If determination section 62 at Step S10A determines that capacitance correction values 91 and 92 do not satisfy any of conditions (10A-1) and (10A-2) (“No” in Step S10A), then determination section 62 at Step S10 determines whether or not object 34C approaches electronic device 100. If determination section 62 at Step S10 determines that object 34C approaches electronic device 100 (“Yes” in Step S10), then determination section 62 in the signal generation (Step S3) generates position signal SG2 indicating the position on which object 34C approaches electronic device 100 and operation signal SG3 indicating the approaching.

An operation of electronic device 100 after the position operated by object 34C is determined by position detection circuit 52 will be described below. While menus, such as plural icons are displayed by display controller 53 on display apparatus 32, the operator has object 34C (finger) approach a position on upper surface 34A of transparent cover 34 on a desired icon, or has object 34C touch upper surface 34A. Then, position detection circuit 52 detects the position of object 34C as the finger and inputs position signal SG2 and operation signal SG3 to display controller 53. Upon receiving position signal SG2 and operation signal SG3, display controller 53 is operable to change the display on display apparatus 32.

According to the embodiment, electronic device 100 is held by the operator in a direction perpendicular to the Y-axis along which electrodes 4101 to 4110 extend. However, the approaching of the object can be determined even if electronic device 100 is held in a direction perpendicular to the X-axis by switching capacitance correction value 91B and capacitance correction value 92B under the holding status determination conditions.

The conditions for determining the holding status, the releasing status, the electromagnetic noise, and the change of the ground level may change depending on each electronic device. Thus, the determination conditions are not limited to the above determination conditions.

Position detection circuit 52 is provided on wiring board 51. However, position detection circuit 52 may be provided on connection board 45 to be integral with touch panel 31.

As described above, electronic device 100 in accordance with the embodiment includes touch panel 31 and position detection circuit 52 operable to output a position signal indicating a position at which touch panel 31 operated with object 34C. Touch panel includes electrodes 4101 to 4110 and electrodes 4301 to 4318 facing electrodes 4101 to 4110. Position detection circuit 52 is operable to execute detecting capacitance measurement values 81 corresponding to capacitances of electrodes 4101 to 4110, respectively, and capacitance measurement values 82 corresponding to capacitances of second electrodes 4301 to 4318, respectively. Position detection circuit 52 is operable to execute performing a correction process to capacitance measurement values 81 to provide capacitance correction values 91, respectively. Position detection circuit 52 is operable to execute performing a correction process to capacitance measurement values 82 to provide capacitance correction values 82, respectively. Position detection circuit 52 is operable to execute determining whether or not electronic device 100 is in a holding status in which electronic device 100 is held based on capacitance measurement values 81, capacitance correction values 91, capacitance measurement values 91, or capacitance correction values 92. Position detection circuit 52 is operable to execute performing a calibration process to correct the correction processes if determining that electronic device 100 is in the holding status. Position detection circuit 52 is operable to execute outputting the position signal based on capacitance measurement values 81, capacitance correction values 91, capacitance measurement values 82, or capacitance correction values 92.

The position detection circuit may be operable to execute providing, in the correction process, capacitance correction values 91 based on reference data 72 and capacitance measurement values 81. The position detection circuit may be operable to execute providing, in the correction process, capacitance correction values 92 based on reference date 73 and capacitance measurement values 82. The position detection circuit may be operable to execute updating, in the calibration process, reference data 72 and 73 if determining that electronic device 100 is in the holding status.

The position detection circuit may be operable to execute providing, in the correction process, capacitance correction values 91 by subtracting reference data 72 from capacitance measurement values 81. The position detection circuit may be operable to execute providing, in the correction process, capacitance correction values 92 by subtracting reference data 73 from second capacitance measurement values 82.

The position detection circuit may be operable to execute providing, in the calibration process, reference data 72 with capacitance measurement values 81. The position detection circuit may be operable to execute providing, in the calibration process, reference data 73 with capacitance measurement values 82.

Electrodes 4101 to 4110 include electrode 4101 located at one end of the array of electrodes 4101 to 4110, electrode 4102 adjacent to electrode 4101, electrode 4110 located at another end of the array of electrodes 4101 to 4110, and electrode 4109 adjacent to electrode 4110. Position detection circuit 52 may be operable to execute determining that electronic device 100 is in the holding status if satisfying all conditions: (1) that at least one of capacitance correction values 91 of electrodes 4101 and 4102 exceeds threshold value TX2; (2) that at least one of capacitance correction values 91 of electrodes 4109 and 4110 exceeds threshold value TX2; (3) that capacitance correction value 91 of electrode 4105 located at a center of electrodes 4101 to 4110 is smaller than threshold value TX2; and (4) that not fewer than half of capacitance correction values 92 exceed threshold value TY2.

Position detection circuit 52 may be operable to execute performing the calibration process if at least one of capacitance correction values 91 and 92 is negative.

Position detection circuit 52 may be operable to repeat, at an interval not longer than 2 seconds, detecting capacitance measurement values 81 and 82, providing first capacitance correction values 91 and 92, and determining whether or not electronic device 100 is in the holding status based on capacitance measurement values 81, capacitance correction values 91, capacitance measurement values 82, or capacitance correction values 92.

Position detection circuit 52 may be operable to execute performing the calibration process if capacitance correction values 91 of three or more electrodes out of electrodes 4101 to 4110 not adjacent to one another exceed threshold value TX3. Position detection circuit 52 may be operable to execute performing the calibration process if capacitance correction values 92 of three or more electrodes out of electrodes 4301 to 4318 not adjacent to one another exceed threshold value TY3.

The position at which touch panel 100 is operated by object 34C is a position at which object 34C approaches touch panel 31 and does not touch the touch panel 31.

Position detection circuit 52 may be operable to execute determining whether the object touches the touch panel or not. If determining that object 34C does not touch the touch panel, position detection circuit 52 may be operable to execute: (1) determining whether or not electronic device 100 is in the holding status, based on capacitance measurement values 81, capacitance correction values 91, capacitance measurement values 81, or capacitance correction values 82; (2) performing the calibration process to correct the correction process if determining that electronic device 100 is in the holding status; (3) outputting the position signal based on capacitance measurement values 81, capacitance correction values 91, capacitance measurement values 82, or capacitance correction values 92. If determining that object 34C touches the touch panel 31, position determination circuit 52 may be operable to execute outputting a signal indicating the position at which object 34C touches the touch panel 31 based on capacitance measurement values 81 or capacitance measurement values 82.

Determination section 62 may perform the holding status determination or abnormality determination using reference data 72 having a single value and threshold values TX1 to TX3 different depending on electrodes 4101 to 4110, respectively. Similarly, determination section 62 may perform the holding status determination or abnormality determination using reference data 73 having a single value and threshold value TY1 to TY3 different depending on electrodes 4301 to 4118, respectively. This operation does not require the calculation of none of capacitance correction values 91 and 92.

As described above, electronic device 100 according to the embodiment performs the calibration process if determination section 62 determines that electronic device 100 is in the holding status based on capacitance measurement values 81 and capacitance measurement values 82 detected in the approaching detection process at electrodes 4101 to 4110 or capacitance correction values 91 and capacitance correction values 92 detected at electrodes 4301 to 4318. Thus, electronic device 100 can prevent object 34C from being falsely detected in the approaching detection.

Electronic device 100 determines whether or not electronic device 100 is in the holding status based on the conditions that two electrodes at both ends of the array of electrodes 4101 to 4110 have capacitance correction values 91 exceeding threshold value TX1, that two center electrodes out of electrodes 4101 to 4110 have capacitance correction values 91 smaller than threshold value TX1, and that not fewer than half of electrodes 4301 to 4318 have capacitance correction values 92 exceeding threshold value TY1, thereby determining the holding status accurately.

Determination section 62 may perform the calibration process if at least one of capacitance correction values 91 detected at electrodes 4101 to 4110 and capacitance correction values 92 detected at electrodes 4301 to 4318 is negative in the approaching detection process. Thus, determination section 62 can avoid the false detection of object 34C when electronic device 100 is released from the holding status.

Furthermore, determination section 62 may determine the holding status at an interval not longer than 2 seconds. Thus, the approaching detection process can be quickly performed when the operator operates electronic device 100.

Furthermore, determination section 62 may perform the calibration process if capacitance correction values 91 detected at three or more electrodes out of electrodes 4101 to 4110 not adjacent to one another exceed threshold value TX3 in the approaching detection process or if capacitance correction values 92 detected at three or more electrodes out of electrodes 4301 to 4318 not adjacent to one another exceed threshold value TY3. Thus, electronic device 100 can avoid the false detection of object 34C even when receiving electromagnetic noise.

In the embodiment, terms, such as “upper surface”, “above”, and “beneath”, indicating directions merely indicate relative directions depending only on the relative positional relation of components, such as touch panel 31 and display apparatus 32 of electronic device 100, and do not indicate absolute directions, such as a vertical direction.

What is claimed is:

1. An electronic device comprising:
a touch panel including a plurality of first electrodes and a plurality of second electrodes facing the plurality of first electrodes; and
a position detection circuit connected to the plurality of first electrodes and the plurality of second electrodes and being operable to output a position signal indicating a position at which the touch panel operated with an object,
wherein the position detection circuit is operable to execute:
detecting the plurality of first capacitance measurement values corresponding to capacitances of the plurality of first electrodes, respectively, and a plurality of second capacitance measurement values corresponding to capacitances of the plurality of second electrodes, respectively;
performing a first correction process to the plurality of first capacitance measurement values to provide a plurality of first capacitance correction values, respectively;
performing a second correction process to the plurality of second capacitance measurement values to provide a plurality of second capacitance correction values, respectively;
determining whether or not the electronic device is in a holding status in which the electronic device is held based on the plurality of first capacitance measurement values, the plurality of first capacitance correction values, the plurality of second capacitance measurement values, or the plurality of second capacitance correction values;
performing a calibration process to correct the first correction process and the second correction process if determining that the electronic device is in the holding status; and
outputting the position signal based on the plurality of first capacitance measurement values, the plurality of first capacitance correction values, the plurality of second capacitance measurement values, or the plurality of second capacitance correction values.

2. The electronic device according to claim 1, wherein the position detection circuit is operable to execute
providing, in the first correction process, the plurality of first capacitance correction values based on first reference data and the plurality of first capacitance measurement values;
providing, in the second correction process, the plurality of second capacitance correction values based on second reference date and the plurality of second capacitance measurement values; and
updating, in the calibration process, the first reference data and the second reference data if determining that the electronic device is in the holding status.

3. The electronic device according to claim 2, wherein the position detection circuit is operable to execute:
providing, in the first correction process, the plurality of first capacitance correction values by subtracting the first reference data from the plurality of first capacitance measurement values; and
providing, in the second correction process, the plurality of second capacitance correction values by subtracting the second reference data from the plurality of second capacitance measurement values.

4. The electronic device according to claim 3, wherein the position detection circuit is operable to execute:
providing, in the calibration process, the first reference data with the plurality of first capacitance measurement values, and
providing, in the calibration process, the second reference data with the plurality of second capacitance measurement values.

5. The electronic device according to claim 1,
wherein the plurality of first electrodes include a third electrode located at one end of an array of the plurality of first electrodes, a fourth electrode adjacent to the third electrode, a fifth electrode located at another end of the array of the plurality of first electrodes, and a sixth electrode adjacent to the fifth electrode, and
wherein the position detection circuit is operable to execute determining that the electronic device is in the holding status if satisfying all conditions:
that at least one of first capacitance correction values out of the plurality of first capacitance correction values of the third electrode and the fourth electrode exceeds a first threshold value;
that at least one first capacitance correction value out of the plurality of first capacitance correction values of the fifth electrode and the sixth electrode exceeds the first threshold value;
that a first capacitance correction value out of the plurality of first capacitance correction values of a first electrode located at a center of the plurality of first electrodes is smaller than the first threshold value; and
that not fewer than half of the plurality of second capacitance correction values exceed a second threshold value.

6. The electronic device according to claim 1, wherein the position detection circuit is operable to execute performing the calibration process if at least one of the plurality of first capacitance correction values and the plurality of second capacitance correction values is negative.

7. The electronic device according to claim 1, wherein the position detection circuit is operable to repeat, at an interval not longer than 2 seconds:
detecting the plurality of first capacitance measurement values and the plurality of second capacitance measurement values;
providing the plurality of first capacitance correction values;
providing the plurality of second capacitance correction values; and
determining whether or not the electronic device is in the holding status based on the plurality of first capacitance measurement values, the plurality of first capacitance correction values, the plurality of second capacitance measurement values, or the plurality of second capacitance correction values.

8. The electronic device according to claim 1, wherein the position detection circuit is operable to execute performing the calibration process if first capacitance correction values out of the plurality of first capacitance correction values of three or more first electrodes out of the plurality of first electrodes not adjacent to one another exceed a first threshold value.

9. The electronic device according to claim 1, wherein the position at which the touch panel is operated by the object is a position at which the object approaches the touch panel and does not touch the touch panel.

10. The electronic device according to claim 9, wherein the position detection circuit is operable to execute:
determining whether the object touches the touch panel or not;
if determining that the object does not touch the touch panel, executing
determining whether or not the electronic device is in the holding status, based on the plurality of first capacitance measurement values, the plurality of first capacitance correction values, the plurality of second capacitance measurement values, or the plurality of second capacitance correction values,
performing the calibration process to correct the first correction process and the second correction process if determining that the electronic device is in the holding status,
outputting the position signal based on the plurality of first capacitance measurement values, the plurality of first capacitance correction values, the plurality of second capacitance measurement values, or the plurality of second capacitance correction values; and
if determining that the object touches the touch panel, outputting a signal indicating a position at which the object touches the touch panel based on the plurality of first capacitance measurement values or the plurality of second capacitance measurement values.

11. The electronic device according to claim 1, wherein the touch panel further includes a transparent cover covering the plurality of first electrodes and the plurality of second electrodes.

12. The electronic device according to claim 1, further comprising:
a display apparatus provided on the touch panel; and
a display controller for controlling a display on the display apparatus based on the position signal.

13. An electronic device comprising:
a touch panel including a plurality of first electrodes and a plurality of second electrodes facing the plurality of first electrodes; and
a position detection circuit connected to the plurality of first electrodes and the plurality of second electrodes the position detection circuit being operable to output a position signal indicating a position at which the touch panel is operated by an object,
wherein the position detection circuit is operable to execute:
detecting a plurality of first capacitance measurement values corresponding to capacitances of the plurality of first electrodes, respectively, and a plurality of second capacitance measurement values corresponding to capacitances of the plurality of second electrodes, respectively;
performing a first correction process to the plurality of first capacitance measurement values to provide a plurality of first capacitance correction values;
performing a second correction process to the plurality of second capacitance measurement values to provide a plurality of second capacitance correction values;
performing a calibration process to correct the first correction process and the second correction process if first capacitance correction values out of the plurality of first capacitance correction values of three or more first electrodes out of the plurality of first electrodes not adjacent to one another exceed a first threshold value; and
outputting the position signal based on the plurality of first capacitance measurement values, the plurality of first capacitance correction values, the plurality of second capacitance measurement values, or the plurality of second capacitance correction values.

14. The electronic device according to claim 13, wherein the touch panel further includes a transparent cover covering the plurality of first electrodes and the plurality of second electrodes.

15. The electronic device according to claim 13, further comprising:
a display apparatus provided on the touch panel; and
a display controller for controlling a display on the display apparatus based on the position signal.
